(19) United States
(12) Patent Application Publication
(10) Pub. No.: US 2021/0385982 A1
(43) Pub. Date: Dec. 9, 2021

(54) APPARATUS FOR USE IN ELECTRONIC EQUIPMENT

(71) Applicant: INTERDIGITAL CE PATENT HOLDINGS, Paris (FR)

(72) Inventors: Wenxin HUANG, Beijing (CN); Ren ZHANG, Beijing (CN); Ai ZHANG, Beijing (CN)

(21) Appl. No.: 16/650,744

(22) PCT Filed: Sep. 29, 2017
(86) PCT No.: PCT/CN2017/104353

§ 371 Date: Mar. 25, 2020

(51) Int. Cl. H05K 9/00

(52) U.S. Cl. CPC H05K 9/0024

(57) ABSTRACT

Apparatus for use in electronic equipment includes a cap of nonconductive material positioned to collect and retain metallic particles produced by installation of metallic fasteners during assembly of the electronic equipment.

### TECHNICAL FIELD

The present principles relate generally to apparatus for use in electronic equipment.

### BACKGROUND

Manufacturing electronic equipment typically involves fastening components together. For example, electronic equipment typically includes components that generate heat such as integrated circuits and other power-consuming components that may be mounted on a circuit board such as a printed circuit board (PCB). The design of electronic equipment typically includes components such as heat sinks and/or heat spreaders to dissipate excessive heat and maintain desired operating temperatures of the equipment. A component intended to dissipate heat from a device such as an integrated circuit (IC) must be positioned in proximity to the device, thermally coupled to the device to ensure efficient conduction of heat from the device to the heat-dissipation component, and fastened in position to ensure thermal coupling and continued heat removal.

Fastening may involve a fastener such as a screw that passes through the component to be held in place, e.g., a heat spreader, and into a threaded hole or opening, e.g., in a structure or assembly to which the heat dissipation component is to be fastened. To provide a reliable and rigid connection, the screw and the threaded hole receiving the screw may be constructed of metal. The action of inserting and tightening a metal fastener such as a screw against the threads of a threaded metal hole may create debris such as small slivers or pieces of metal that break away from the screw and/or the threaded hole. These slivers of metal are conductive. If the pieces fall onto other components, devices or structures of the electronic equipment, such as an IC or a printed circuit board (PCB) they may cause a short circuit resulting in a failure of the electronic equipment. The slivers may be created during production but not cause a failure of the equipment initially, e.g., during testing. Then, subsequent movement of the electronic equipment, e.g., during installation, may dislodge the slivers of metal causing them to move within the electronic equipment and cause a failure at that time. The result is reduced reliability of the electronic equipment.

### SUMMARY

These and other drawbacks and disadvantages of the prior art are addressed by the present principles.

In accordance with an aspect of the present principles, an embodiment of apparatus comprises a structure configured for use in an electronic device and having an opening for receiving a fastener, and a cap mounted on an underside of a portion of the structure at a position beneath the opening, wherein the cap is configured to capture and retain a conductive particle created by insertion of the fastener into the opening.

In accordance with another aspect, an embodiment of apparatus as described herein may include a cap having a body portion and first and second extension portions extending away from opposite sides of the body portion.

In accordance with another aspect, an embodiment of apparatus as described herein including a structure and a cap having first and second extension portions may be configured to have the first and second extension portions fit within respective first and second slots of the structure to retain the cap in a position beneath an opening of the structure.

In accordance with another aspect, an embodiment of apparatus as described herein including a structure having first and second slots may be configured to form the first and second slots from respective first and second tabs of a planar portion of the structure bent away from the planar portion into respective first and second positions proximate the opening.

In accordance with another aspect, an embodiment of apparatus as described herein including a structure and a cap may be configured to include a recessed portion in the cap wherein the recess portion is positioned beneath an opening in the structure to capture and retain a conductive particle.

In accordance with another aspect, an embodiment of apparatus as described herein including a structure having an opening may be configured such that the opening includes a perimeter having a threaded portion to receive a threaded shaft of a fastener.

In accordance with another aspect, an embodiment of apparatus as described herein may include a cap comprising a non-conductive material.

In accordance with another aspect, an embodiment of apparatus as described herein may include a cap comprising a compressible elastic material.

In accordance with an aspect of the present principles, an embodiment comprises apparatus including a shielding cover configured for attachment to a circuit board to cover and reduce an electromagnetic emission from an electronic component mounted on the circuit board;

a first region of the shielding cover having an opening allowing an end of a fastener to pass through the shielding cover for fastening a thermal dissipation component to an upper side of the shielding cover; a second region of the shielding cover on a lower side of the shielding cover and including a portion extending away from the second side in an area proximate to the opening to form a retaining member; and a cap of non-conductive material configured to be held in a position on the lower side of the shielding cover by the retaining member and cover the opening in the first region of the shielding cover.

In accordance with another aspect, an embodiment of a cap included in apparatus as described herein comprises an elastic material configured to capture a metallic particle created by insertion of the fastener into the opening during assembly of the apparatus, thereby preventing the metallic particle from falling on to the PC board.

In accordance with another aspect, an embodiment of apparatus as described herein may include a shielding cover having a retaining member configured to include first and second slots formed from respective first and second tabs of a planar portion of the shielding cover bent away from the planar portion into respective first and second positions proximate an opening in the shielding cover.

In accordance with another aspect, an embodiment of apparatus as described herein may include a cap having a rectangular body portion and first and second extension portions extending away from opposite sides of the body portion.

In accordance with another aspect, an embodiment of apparatus as described herein including a shielding cover and a cap may include having first and second extension portions of the cap configured to fit within respective ones of first and second slots formed in the shielding cover to retain the cap in a position beneath an opening in the shielding cover.

In accordance with another aspect, an embodiment of apparatus as described herein including a shielding cover having first and second slots and a cap having first and second extension portions may include the cap comprising an elastic material and include the first and second extension portions being formed from the elastic material and compressing to fit into the first and second slots.

In accordance with another aspect, an embodiment of apparatus as described herein including a shielding cover and a cap may include the cap being configured to have a recessed portion positioned beneath an opening in the shielding cover to capture and retain a metallic particle created by insertion of the fastener into the opening during assembly of the apparatus, thereby preventing the metallic particle from falling on to a circuit board.

These and other aspects, features and advantages of the present principles will become apparent from the following detailed description of exemplary embodiments, which is to be read in connection with the accompanying drawings.

### BRIEF DESCRIPTION OF THE DRAWINGS

The present principles can be readily understood by considering the following detailed description in conjunction with the accompanying drawings in which:

FIG. 1 shows an exemplary embodiment of apparatus illustrating aspects of the present principles;

FIG. 2 shows an enlarged view of one portion of the apparatus shown in FIG. 1; and

FIG. 3 through FIG. 10 show various views of exemplary apparatus illustrating aspects of the present principles.

It should be understood that the drawings are for purposes of illustrating exemplary aspects of the present principles and are not necessarily the only possible configurations for illustrating the present principles. To facilitate understanding, throughout the various figures like reference designators refer to the same or similar features.

### DETAILED DESCRIPTION

The present principles are directed to apparatus providing increased reliability for electronic equipment and, as will be apparent to one skilled in the art, may be applied to other situations. While one of ordinary skill in the art will readily contemplate various applications to which the present principles can be applied, the following description will focus on exemplary embodiments of the present principles applied to electronic equipment such as set top boxes (STB), gateway devices, digital televisions, modems, display devices, power supplies, etc. that include at least one printed circuit board (PCB) as described herein. However, one of ordinary skill in the art will readily contemplate various other embodiments of the present principles. It is to be appreciated that the preceding listing of potential applications of the present principles is merely illustrative and not exhaustive.

As a further example of a potential application of the present principles, active components such as digital integrated circuits (ICs), e.g., microprocessors, microcontrollers, system-on-a-chip (SOC), etc., typically operate with digital signals at high frequencies. Such signals may generate high frequency noise that could propagate within an electronic device and interfere with the operation of other components. To limit noise propagation, high frequency components such as microprocessors may be positioned within a conductive shield. For example, one part of a shield may be positioned on a circuit board such as a printed circuit board (PCB) in the form of a conductive wall or frame surrounding a region where a noise-generating component is to be mounted on the PCB. The conductive frame is coupled to a reference potential, e.g., ground. During production, the noise-generating component is mounted to the PCB within the shield region formed by the frame. After the component is mounted to the PCB, a structure or assembly such as a conductive lid or cover is placed over the shielded region and fastened to the frame enclosing the noise-generating component in a grounded, conductive box or container comprising the frame and the cover that effectively prevents high-frequency noise from propagating beyond the container. One approach to fastening the cover to the frame comprises a sequence of conductive clips around a perimeter of the cover that engage the frame when the cover is placed in position and pushed on to the frame during assembly. The clips hold the cover to the frame, thereby holding the cover in place, coupling the cover to the reference potential, and forming a shielding container for the noise-producing component or components within the container.

It may be necessary to provide for removing heat produced by the device within the container. One approach is to provide an opening in the cover over the device and thermally couple a heat sink or heat spreader to the device through the opening in the cover. A heat sink or heat spreader is typically metallic to effectively conduct heat away from a heat-generating device and placing a metallic heat spreader or heat sink over the opening in the container cover maintains the shielding effect of the container. The heat sink or heat spreader may be fastened to the cover of the container by inserting fasteners, e.g., screws, through openings or holes in the heat spreader or heat sink and into openings or holes in the cover of the container. However, if the screws are metallic and they are inserted through holes in the metallic heat sink or heat spreader and into threaded openings or holes in the metallic cover of the container then there is a possibility of creating slivers of metal that, as described above, may fall onto the PCB within the container and/or onto components on the PCB, thereby introducing the possibility of a short circuit causing a failure of the electronic equipment as explained above.

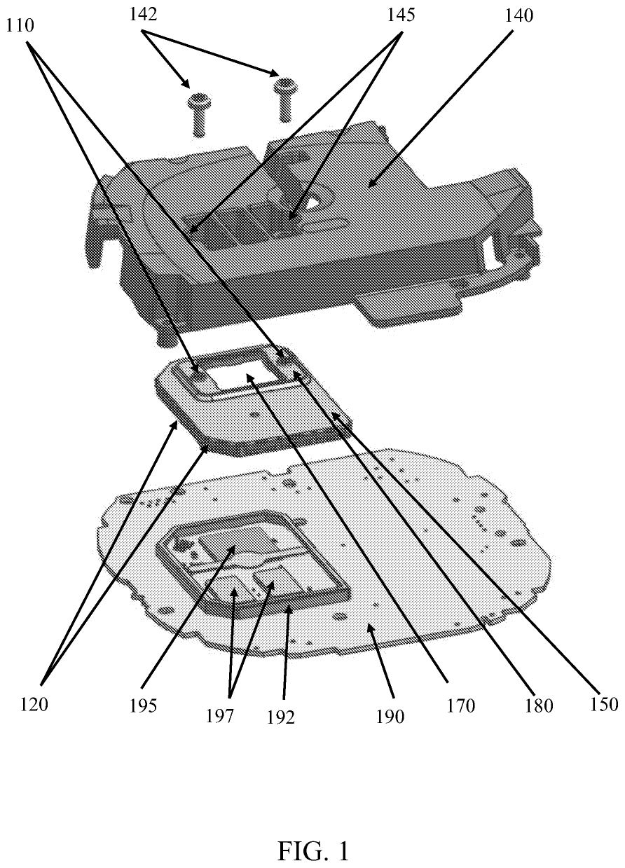

Referring now to FIG. 1, an exemplary embodiment of apparatus illustrating aspects of the present principles includes a heat dissipation component 140 such as a heat spreader, a structure 150 such as a shield cover, and a circuit board 190 such as a PCB. For ease of explanation, the following description will refer to component 140 as a heat spreader, structure 150 as a cover or shield cover, and circuit board 190 as a PCB. However, it will be readily apparent to one skilled in the art that the present principles are applicable to various other types of components and devices. For example, structure 150 may be an assembly, board or other structure; component 140 may be any of various types of heat dissipation components such as a heat sink; circuit board 190 may be of any form of which PCB is merely an example. Continuing with FIG. 1, a shield frame 192 is mounted on PCB 150 within which various components that generate noise and heat are mounted, e.g., microcontroller 195 and other components 197. Shield cover 150 includes a top surface having a raised area 180 with an opening 170 and holes 110. Shield cover 150 also includes tabs 120 that engage frame 192 when cover 150 is pressed onto frame 192 during assembly. After assembly, tabs 120 hold cover 150 in place on top of frame 192 to form a shielding container. Heat spreader 140 includes recessed areas 145. During assembly, fasteners 142, e.g., screws, are inserted into recessed areas 145, through holes at the bottom of recessed areas 145, and into holes 110 in container cover 150. If fasteners 142 are screws then holes 110 may be threaded and fasteners 142 screwed into holes 110 to fasten heat spreader 140 to cover 150. A portion of heat spreader 140 is configured to extend through opening 170 in cover 150 and contact a device such as 195 to conduct heat away from the device. Heat spreader 140 also covers opening 170, thereby sealing the opening and maintaining the noise limiting effect of the container.

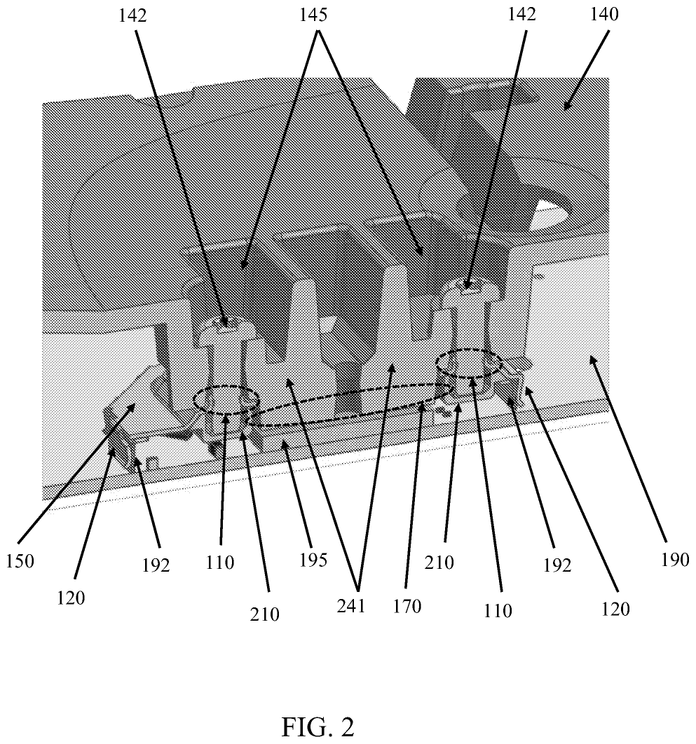

FIG. 2 provides an enlarged and cross section view of aspects of the exemplary embodiment in FIG. 1. In FIG. 2, container cover 150 is assembled on to container frame 192 mounted on PCB 190 with tabs 120 engaging frame 192. Heat spreader 140 is shown mounted on to container cover 150 and a portion 241 of heat spreader 140 extending through opening 170 in cover 150 to be in thermal contact with device 195. The cross section shown in FIG. 2 is taken through the assembled combination of PCB 190, container cover 150 and heat spreader 140 and, more specifically, through recesses 145 in heat spreader 140. In FIG. 2, screws 142 are shown inserted into recesses 145, through holes in the bottom of the recesses 145 and into holes 110 in container cover 150. The perimeter of holes 110 may be threaded to engage the threads of screws 142, thereby fastening heat spreader 140 against cover 150 and holding portion 241 of heat spreader 140 in thermal contact with device 195. In accordance with an aspect of the present principles, FIG. 2 also shows two caps 210 with one positioned under each of screws 142 as will be explained in more detail below.

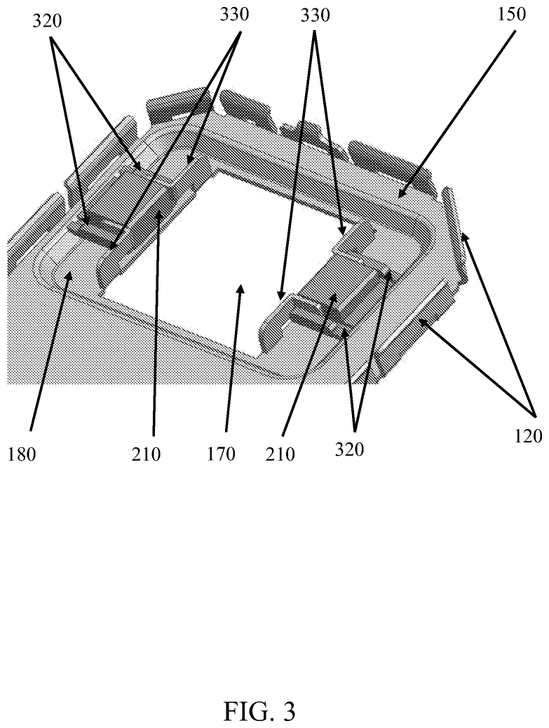

The views of container cover 150 shown in FIG. 1 and FIG. 2 illustrate one side of cover 150, i.e., a side that is positioned toward heat spreader 140 and away from PCB 190 that will hereinafter be referred to as the first, top or upper side of cover 150. A second side of cover 150 or the side that is positioned toward PCB 190 and away from heat spreader 140 will be referred to as the second, bottom or lower side of cover 150. FIG. 3 illustrates a view of a portion of the second or lower side of cover 150 in the region under raised area 180 shown in FIG. 1. In FIG. 3, an exemplary embodiment of caps 210 referred to above in regard to FIG. 2 are shown in more detail. Each of caps 210 has a body portion that is rectangular in the exemplary embodiment shown in FIG. 3 and first and second side portions or extensions 320 on opposite sides of the body portion. The side portions or extensions fit under tabs 330 to retain caps 210 in position on the second or under side of cover 150 and, more specifically, under the opening of holes 110 (not visible in FIG. 3). Tabs 330 may be formed by bending portions of metal of cover 150 that is along the edges of opening 170 downward during manufacturing of cover 150. Tabs 330 are formed to provide a space or gap between an edge of tabs 330 and the underside of cover 150 having a width and height of the body of caps 210, i.e., the portion of caps 210 between extensions 320. Caps 210 are inserted through this gap during assembly. Each of tabs 330 also has a portion bent at a right angle to and away from the edge of opening 170. Each bent portion engages a slotted portion of a respective one of extensions 320 to prevent caps 210 from moving sideways. Caps 210 may be made of flexible, non-conductive, flexible material, e.g., rubber or plastic that enables side extensions 320 to compress slightly during assembly. That is, assembly involves sliding caps 210 from opening 170 under tabs 330 along the underside of cover 150 until an edge of each of caps 210 distal from opening 170 reaches an edge of raised area 180. At that point extensions 320 that are slightly shorter than the length of the body of caps 210 decompress or expand inside tabs 330 to retain or lock caps 210 in place.

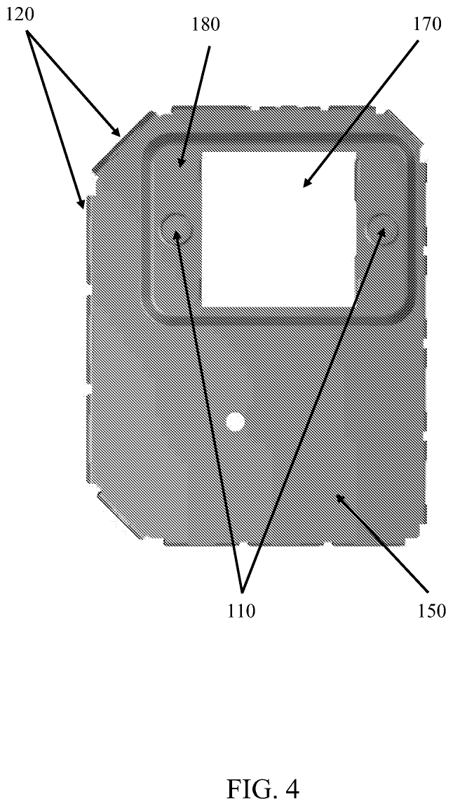

FIG. 4 provides an enlarged view of an embodiment of the first, top or upper side of cover 150. FIG. 4 more clearly shows raised area 180, opening 170 and holes 110 in cover 150.

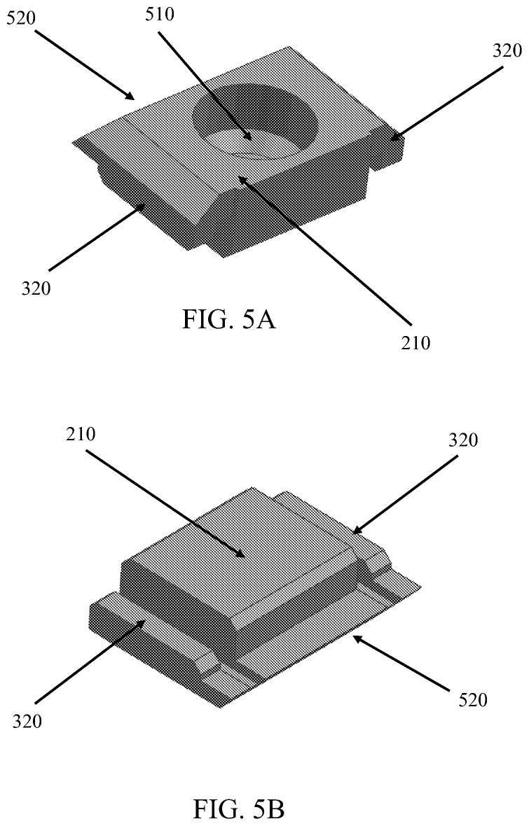

FIGS. 5A and 5B show two views of an embodiment of one of caps 210 illustrating aspects of the present principles. In FIG. 5A, a top perspective view from the side of cap 210 that will be toward opening 170 in cover 150 after assembly. The edge of cap 210 that is toward opening 170 is illustrated as being flat so as to not protrude into opening 170. Edge 520 is on the opposite side of the body portion of cap 210 from the edge toward opening 170. Edge 520 has a sloped profile to substantially match that of the edge of raised region 180 of cover 150. As a result, when caps 210 are inserted under tabs 330 during assembly as explained above in regard to FIG. 3, sloped edge 520 will fit against the edge of raised area 180 when caps 210 are fully inserted. FIG. 5A also shows extensions 320 being slightly shorter than the body of cap 210 as described above, i.e., shown as indented with respect to the edge of cap 210 that is positioned toward opening 170. Area 510 shown in FIG. 5A is a recessed region that will be underneath holes 110 when caps 210 are in position following assembly and will serve at least two purposes in accordance with the present principles. First, recessed region 510 enables the tip of fastener 142 to protrude through hole 110 when assembled. In addition, recessed region 510 catches or captures any conductive debris such as conductive particles or slivers of metal that may fall from or through holes 110 during assembly as described above. Thus, caps 210 prevent such slivers of metal from falling onto components mounted on PCB 190 or on to components mounted on PCB 190, thereby preventing potential failures due to such slivers and improving reliability of the electronic equipment.

FIG. 5B illustrates a bottom perspective view of one of caps 210 from the side of edge 520. FIG. 5B more clearly shows extensions 320 including the slots mentioned above between the extensions and the body of cap 210 that engage tabs 330 during assembly.

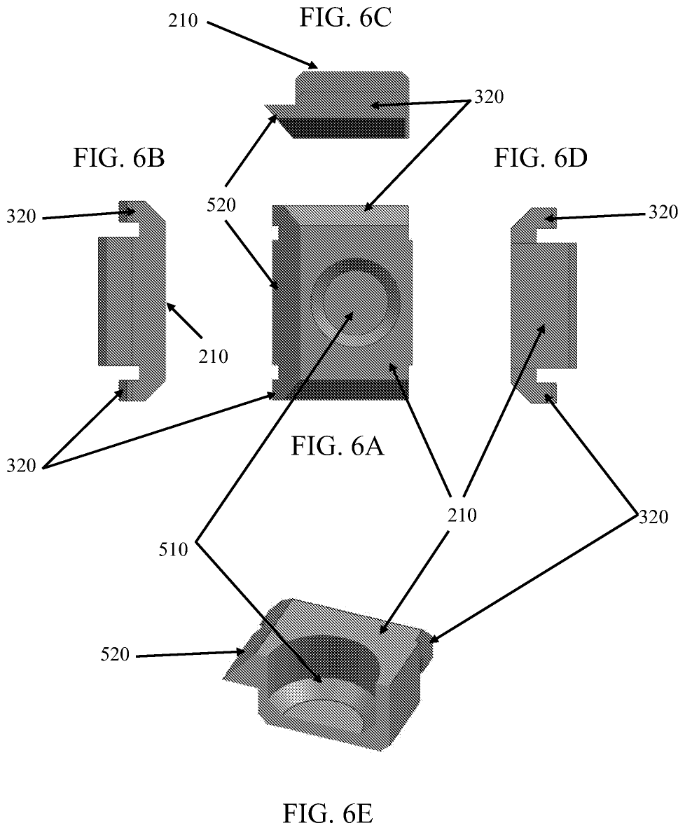

FIGS. 6A through 6E show various views of an embodiment of one of caps 210. These figures show more detail of features described above including the recessed region 510 (FIGS. 6A and 6E), sloped edge 520 (FIGS. 6A, 6C, and 6E), extensions 320 and the associated slots (FIGS. 6B and 6D).

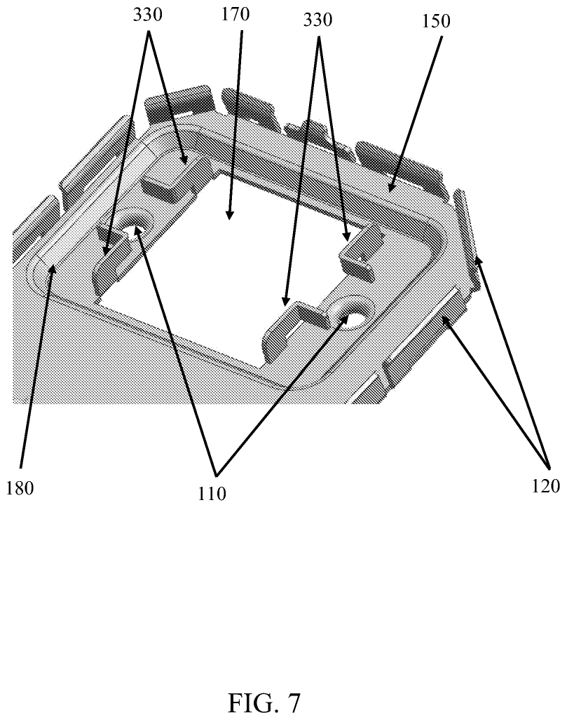

FIG. 7 is a view of the second or underside of cover 150 similar to the view shown in FIG. 3 except that caps 210 shown in FIG. 3 are removed or not in place in FIG. 7. As a result, FIG. 7 more clearly shows an embodiment of tabs 330 including the portion bent at right angles to the edge of opening 170 and the gap between an edge of each tab and the underside of cover 150 forming the slot into which caps 210 are inserted. FIG. 7 also shows the location of holes 110 that are not visible in FIG. 3.

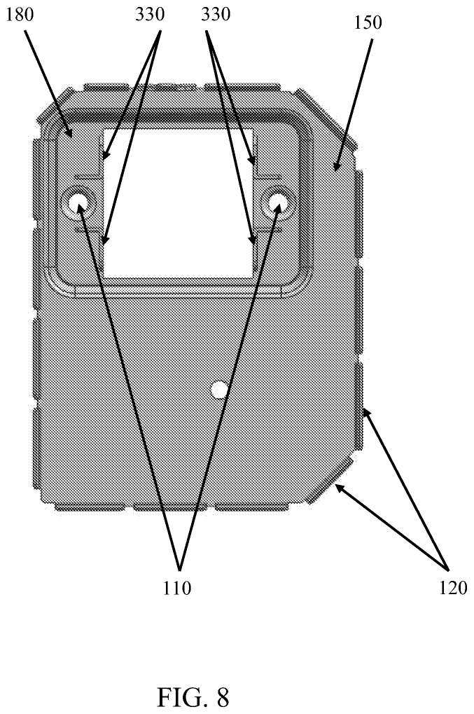

FIG. 8 shows a view of an embodiment of cover 150 similar to that of FIG. 4 but of the underside or second side cover 150. FIG. 8 illustrates features described above.

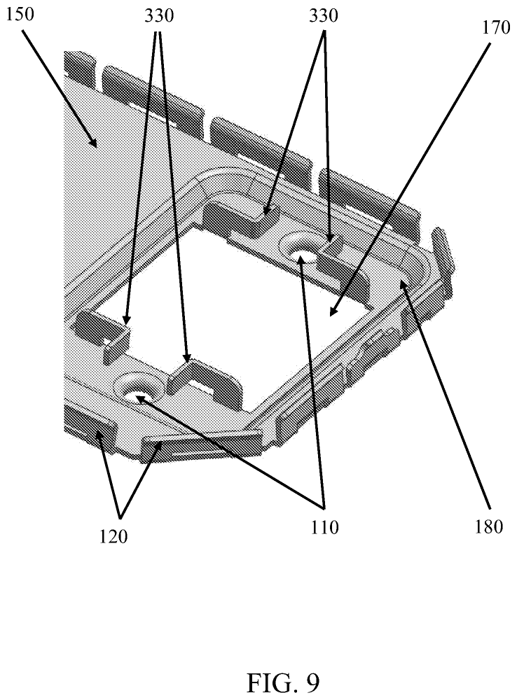

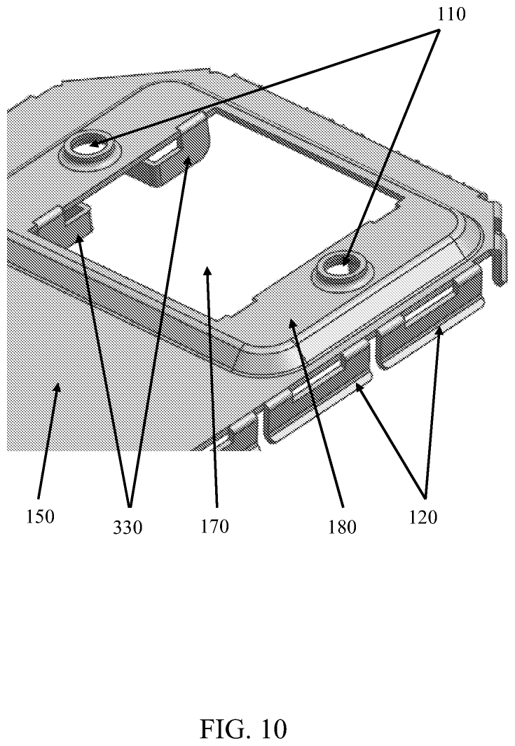

For additional clarity, FIG. 9 shows a different perspective of the underside of cover 150 in comparison to FIG. 7 and illustrates an exemplary embodiment of features described in regard to FIG. 7. FIG. 10 shows an enlarged view of the upper side of the embodiment of cover 150 shown in FIG. 4. In particular, FIG. 10 shows raised region 180 from a perspective that further illustrates features of an embodiment of tabs 330.

The description provided herein illustrates the present principles. It will thus be appreciated that those skilled in the art will be able to devise various arrangements that, although not explicitly described or shown herein, embody the present principles and are included within its spirit and scope. For example, the arrangement or pattern of features included in region 220 of FIG. 2 may be formed using one or more of various techniques such as embossing, molding, shaping, stamping, machining, etc.

All examples and conditional language recited herein are intended for pedagogical purposes to aid the reader in understanding the present principles and the concepts contributed by the inventor(s) to furthering the art, and are to be construed as being without limitation to such specifically recited examples and conditions. For example, use in the description when referring to the drawings of “top”, “bottom”, “left”, “right” and other such terms indicating an orientation or relative relationship between areas of the Figures are illustrative only and not limiting as to the present principles.

Moreover, all statements herein reciting principles, aspects, and embodiments of the present principles, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well as any other variations, appearing in various places throughout the specification are not necessarily all referring to the same embodiment.

Although the illustrative embodiments have been described herein with reference to the accompanying drawings, it is to be understood that the present principles are not limited to those precise embodiments, and that various changes and modifications may be effected therein by one of ordinary skill in the pertinent art without departing from the scope or spirit of the present principles. All such changes and modifications are intended to be included within the scope of the present principles as set forth in the appended claims.

1. Apparatus comprising:
a structure configured for use in an electronic device and having an opening for receiving a fastener; and
a cap mounted on an underside of a portion of the structure at a position beneath the opening, wherein the cap is configured to capture and retain a conductive particle created by insertion of the fastener into the opening.

2. The apparatus of claim 1 wherein
the cap has a body portion and first and second extension portions extending away from opposite sides of the body portion.

3. The apparatus of claim 2 wherein
the first and second extension portions fit within respective first and second slots of the structure to retain the cap in the position beneath the opening.

4. The apparatus of claim 3 wherein
the first and second slots are formed by respective first and second tabs of a planar portion of the structure bent away from the planar portion into respective first and second positions proximate the opening.

5. The apparatus of claim 4 wherein
the cap includes a recessed portion positioned beneath the opening to capture and retain the conductive particle.

6. The apparatus of claim 5 wherein
the opening includes a perimeter having a threaded portion to receive a threaded shaft of the fastener.

7. The apparatus of claim 6 wherein
the cap comprises a non-conductive material.

8. The apparatus of claim 7 wherein
the non-conductive material comprises a compressible elastic material and the first and second extension portions of the cap compress to fit into the first and second slots.

9. Apparatus comprising:
a shielding cover configured for attachment to a circuit board to cover and reduce an electromagnetic emission from an electronic component mounted on the circuit board;
a first region of the shielding cover having an opening allowing an end of a fastener to pass through the shielding cover for fastening a thermal dissipation component to an upper side of the shielding cover;
a second region of the shielding cover on a lower side of the shielding cover and including a portion extending away from the second side in an area proximate to the opening to form a retaining member; and
a cap of non-conductive material configured to be held in a position on the lower side of the shielding cover by the retaining member and cover the opening in the first region of the shielding cover.

10. The apparatus of claim 9 wherein
the retaining member comprises first and second tabs of a planar portion of the shielding cover bent away from the planar portion into respective first and second positions proximate the opening to form first and second slots.

11. The apparatus of claim 10 wherein
the cap has a rectangular body portion and first and second extension portions extending away from opposite sides of the body portion.

12. The apparatus of claim 11 wherein
the first and second extension portions fit within respective ones of the first and second slots to retain the cap in a position beneath the opening.

13. The apparatus of claim 12 wherein
the cap comprises an elastic material and the first and second extension portions formed from the elastic material compress to fit into the first and second slots.

14. The apparatus of claim 13 wherein
the cap includes a recessed portion positioned beneath the opening and configured to capture and retain a metallic particle created by insertion of the fastener into the opening during assembly of the apparatus, thereby preventing the metallic particle from falling on to the circuit board.

15. The apparatus of claim 8 wherein
the apparatus is configured for use in electronic equipment comprising one of one of a set top box, a gateway device, and a digital television device.

16. The apparatus of claim 14 wherein
the apparatus is configured for use in electronic equipment comprising one of a set top box, a gateway device, and a digital television device.
